(19) United States
(12) Patent Application Publication
(10) Pub. No.: US 2026/0202489 A1
(43) Pub. Date: Jul. 16, 2026

(54) METHOD AND SYSTEM FOR DETECTING DEFECT IN BATTERY IN FORMATION PROCESS

(71) Applicant: SK On Co., Ltd., Seoul (KR)

(72) Inventors: Seung Hoon JUNG, Daejeon (KR); Woo Seop KIM, Daejeon (KR); Joo Eun LEE, Daejeon (KR); Kyung Hee JEONG, Daejeon (KR); Seon Hui CHOI, Daejeon (KR)

(21) Appl. No.: 19/444,067

(22) Filed: Jan. 8, 2026

(30) Foreign Application Priority Data
Jan. 10, 2025 (KR) 10-2025-0004225

(51) Int. Cl. G01R 31/396; G01R 31/3835; H01M 10/42

(52) U.S. Cl. CPC G01R 31/396; G01R 31/3835; H01M 10/4285

(57) ABSTRACT

A method for detecting a defect in a battery in a formation process is disclosed. In some implementations, the method includes: measuring a voltage of a battery cell immediately after depressurization of a pressurized battery cell in the formation process; and analyzing a difference between a pattern of the voltage and a reference pattern and detecting a defect in the battery cell based on an analysis result, wherein the analyzing includes analyzing the difference between the voltage pattern and the reference pattern within a short time range of less than one day and within a minute voltage range of less than 1 millivolt (mV).

### CROSS-REFERENCE TO RELATED APPLICATION(S

This patent document claims the priority and benefits of Korean Patent Application No. 10-2025-0004225 filed on January 10, 2025, the disclosure of which is incorporated herein by reference in its entirety.

### TECHNICAL FIELD

The disclosure and implementations disclosed in this patent document generally relate to a method and a system for detecting a defect in a battery in a formation process thereof.

### BACKGROUND

In a battery, a secondary battery has the convenience of being chargeable and dischargeable, unlike a primary battery, and thus has been identified as a power source for various mobile devices, electric vehicles, and the like. The secondary battery may include a battery cell in which an electrode assembly formed by stacking or winding a positive electrode plate, a negative electrode plate, and a separator in a roll shape is accommodated in a case. A plurality of battery cells may be stacked in a predetermined direction and accommodated in a battery module or a battery pack. The battery pack may include the plurality of battery modules.

Detecting a defect occurring in a battery during a battery manufacturing process is important in securing battery safety. Productivity of the battery manufacturing process may be improved as efficiency of battery defect detection increases.

### SUMMARY

The present disclosure can be implemented in some embodiments to provide a method and a system for detecting a defect in a battery in a formation process, the method and the system being capable of efficiently detecting a defect (e.g., a low-voltage defect) in the battery during the formation process thereof (e.g., not only shortening time required for battery defect detection but also improving battery defect detection performance).

In some embodiments of the present disclosure, provided is a method for detecting a defect in a battery in a formation process, the method including: measuring a voltage of a battery cell immediately after depressurization of a pressurized battery cell in the formation process; and analyzing a difference between a pattern of the voltage and a reference pattern and detecting a defect in the battery cell based on an analysis result, wherein the analyzing includes analyzing the difference between the voltage pattern and the reference pattern within a short time range of less than one day and within a minute voltage range of less than 1 millivolt (mV).

The time range may be less than one hour, and the voltage range is less than 0.1 mV.

The time range may be less than 20 seconds, and the voltage range is less than 0.05 mV.

The time range may start from a press-end time point of the battery cell.

The depressurization may include depressurization of press pre-charge (PPC) of the battery cell.

The method may further include: a subsequent process of performing at least one of aging for stabilizing the battery cell or degassing for removing gas inside the battery cell, after the analyzing.

The method may further include: manufacturing the battery cell by coupling a battery case to battery electrodes and injecting an electrolyte into the battery case, prior to the measuring.

The measuring may further include measuring a voltage of the battery cell before the depressurization, and the analyzing may further include analyzing the difference between the voltage change pattern from the voltage of the battery cell measured before the depressurization to the voltage measured after the depressurization and the reference voltage change pattern.

The analyzing may include analyzing a difference between an average of the voltage within the time range and an average of a reference voltage.

The analyzing may include analyzing a difference between a slope of the voltage from a press-end time point of the battery cell to a time point after a predetermined period and a slope of a reference voltage.

The analyzing may include generating information that the battery cell is defective when an absolute value of the slope of the voltage from the press-end time point to the time point after the predetermined period is greater than an absolute value of the slope of the reference voltage.

The analyzing may include analyzing whether the slope of the voltage from the press-end time point to the time point after the predetermined period is positive or negative, generating information that the battery cell is defective when the slope of the voltage is one of positive and negative, and generating information that the battery cell is normal when the slope of the voltage is the other of positive and negative.

In some embodiments of the present disclosure, provided is a system for detecting a defect in a battery in a formation process, the system including: a press device for pressing a battery cell undergoing the formation process; a measuring instrument for measuring a voltage of the battery cell immediately after depressurization; and a controller for analyzing a difference between a pattern of the voltage and a reference pattern and detecting a defect in the battery cell based on an analysis result, wherein the controller analyzes the difference between the voltage pattern and the reference pattern within a short time range of less than one day and within a minute voltage range of less than 1 millivolt (mV).

The time range may be less than one hour, the voltage range is less than 0.1 mV, and the time range starts from a press-end time point of the battery cell.

The time range may be less than 20 seconds, and the voltage range is less than 0.05 mV.

The pressing may include press pre-charge (PPC) pressing of the battery cell.

The measuring instrument may further measure a voltage of the battery cell before the depressurization, and the controller may further analyze the difference between the voltage change pattern from the voltage of the battery cell measured before the depressurization to the voltage measured after the depressurization and the reference voltage change pattern.

The controller may analyze a difference between an average of the voltage within the time range and an average of a reference voltage, or analyze a difference between a slope of the voltage from a press-end time point of the battery cell to a time point after a predetermined period and a slope of the reference voltage.

The controller may include generating information that the battery cell is defective when an absolute value of a slope of the voltage from the press-end time point to the time point after the predetermined period is greater than an absolute value of a slope of the reference voltage.

The controller may analyze whether the slope of the voltage from the press-end time point to the time point after the predetermined period is positive or negative, generate information that the battery cell is defective when the slope of the voltage is one of positive and negative, and generate information that the battery cell is normal when the slope of the voltage is the other of positive and negative.

### BRIEF DESCRIPTION OF DRAWINGS

Certain aspects, features, and advantages of the present disclosure are illustrated by the following detailed description with reference to the accompanying drawings.

FIG. 1 is a flowchart illustrating battery processes including a formation process in a method and a system for detecting a defect in a battery in a formation process according to an embodiment of the present disclosure.

FIGS. 2A and 2B are flowcharts illustrating timing of detecting a defect in the formation process in the method and the system for detecting a defect in a battery during the formation process according to an embodiment of the present disclosure.

FIGS. 3A through 3C are perspective views illustrating depressurization and measurement of a battery cell in the method and the system for detecting a defect in a battery during the formation process according to an embodiment of the present disclosure.

FIG. 4 is a graph illustrating a voltage pattern measured for a defective battery cell immediately after depressurization and a reference pattern measured immediately after depressurization in a method and a system for detecting a defect in a battery in a formation process according to an embodiment of the present disclosure.

FIG. 5 is a graph illustrating a voltage pattern measured for a defective battery cell immediately after depressurization and a reference pattern measured immediately after depressurization in a method and a system for detecting a defect in a battery in a formation process according to an embodiment of the present disclosure.

### DETAILED DESCRIPTION

Features of the present disclosure disclosed in this patent document are described by example embodiments with reference to the accompanying drawings.

The present disclosure can be implemented in some embodiments to provide a method and a system for detecting a defect in a battery in a formation process.

Before describing embodiments of the present disclosure in detail, it should be understood that the terms or words used in the following description and claims are not to be limited to ordinary or dictionary meanings, and should be interpreted as meanings and concepts conforming to the spirit of the present disclosure, based on a principle that an inventor may properly define the concept of terms to describe the inventor’s invention in the best manner.

The same reference numerals or symbols illustrated in the respective drawings denote parts or components that perform substantially the same function. For convenience of description and understanding, the same reference numerals or symbols may be used for description even in different embodiments.

In the following description, a term of a singular number includes its plural number unless the context clearly indicates otherwise. Terms such as “include” or “configure” and similar expressions are intended to specify the presence of the features, numbers, processes, operations, components, parts, or combinations thereof described in the specification, and are not intended to preclude the possibility of the presence or addition of one or more other features, numbers, processes, operations, components, parts, or combinations thereof.

In addition, in the following description, expressions such as upper side, upper portion, lower side, lower portion, side, front, and rear are used based on directions illustrated in the drawings, and it is previously stated that such expressions may be expressed differently when a direction of a corresponding object is changed.

In addition, in the following description and the claims, terms including ordinals such as “first” and “second” may be used to distinguish components from each other. Such ordinals are used to distinguish the same or similar components and should not be construed as limiting meanings of terms due to the use of the ordinals. For example, components coupled with the ordinals should not be construed as being limited in order of use or order of arrangement by their numbers. If necessary, the respective ordinals may be interchanged and used.

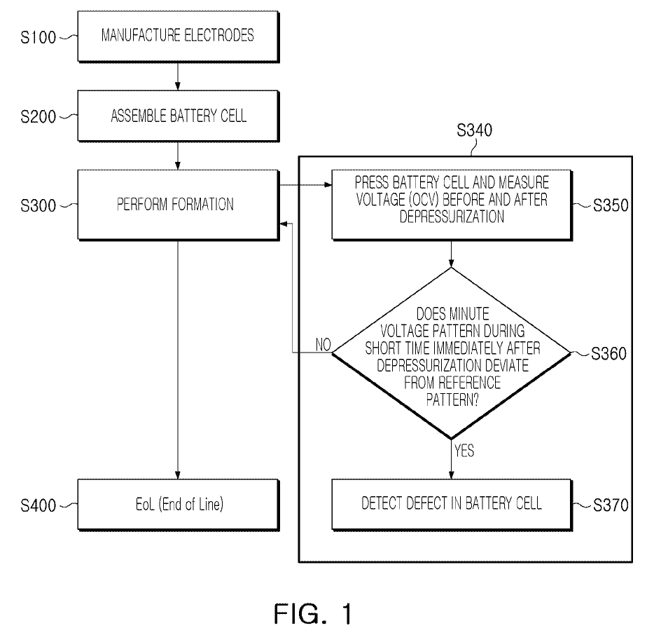

Referring to FIG. 1, the formation process (S300) included in a method and a system for detecting a defect in a battery in a formation process according to an embodiment of the present disclosure may be one process among sequentially performed battery processes (S100, S200, S300, and S400). The battery processes may include an electrode manufacturing process (S100), a battery cell assembly process (S200), the formation process (S300), and an End of Line (EoL) process (S400). The EoL process may be a post-process of a battery.

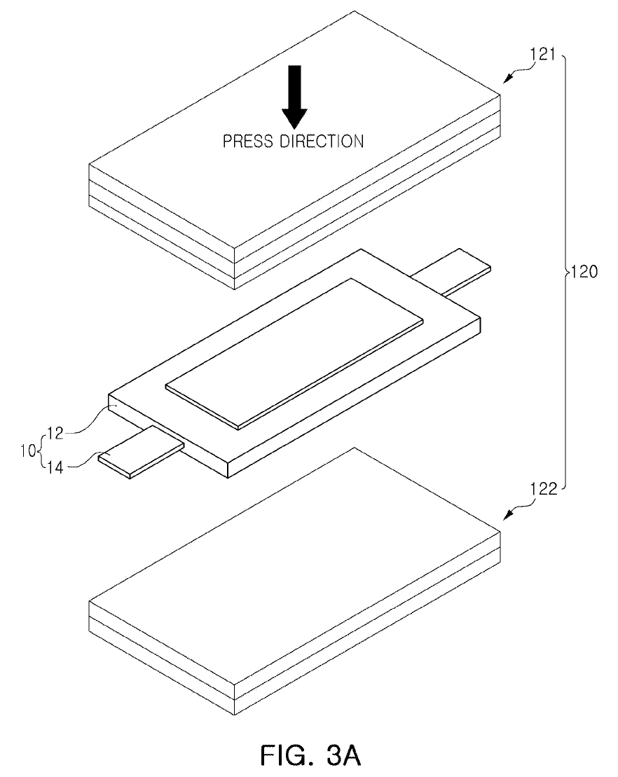

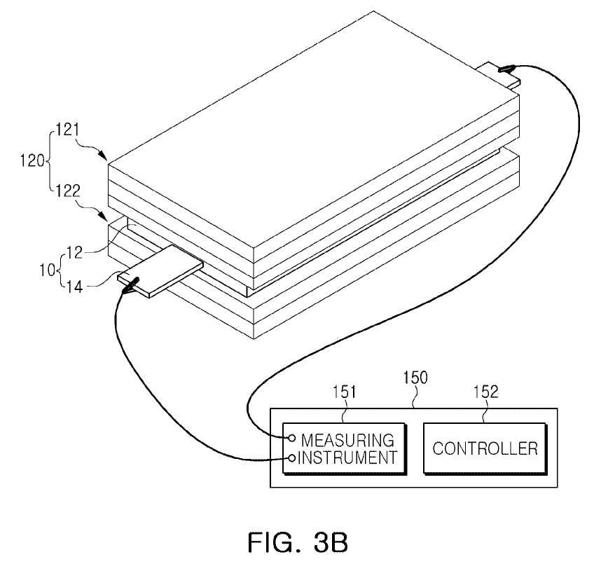

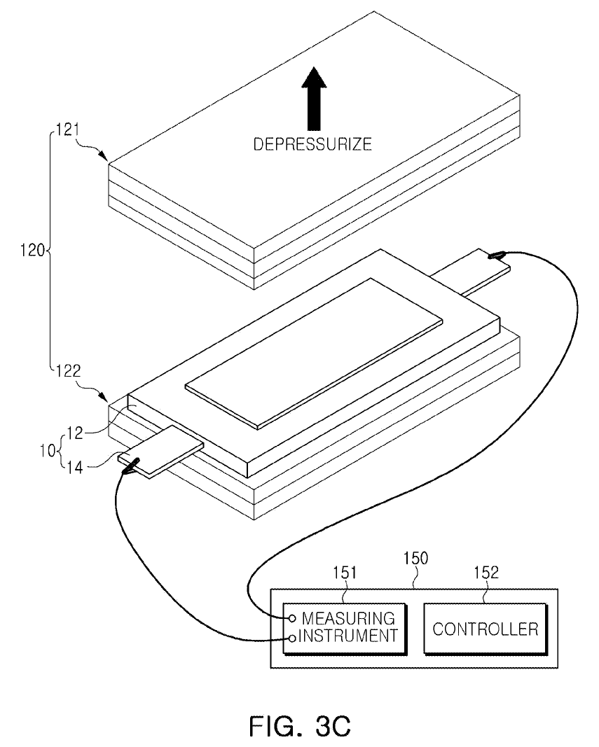

The electrode manufacturing process (S100) may include manufacturing battery electrodes 14 (see FIG. 3A) of at least one battery cell 10 (see FIG. 3A). For example, the electrode manufacturing process (S100) may include forming a slurry by mixing an active material, a conductive material, a binder, and a solvent, coating the slurry on both surfaces of a positive plate (e.g., aluminum plate or copper plate), rolling the coated positive plate, forming electrodes by slitting the coated and rolled positive plate, vacuum drying the electrodes, and manufacturing the battery electrodes 14 (see FIG. 3A) by notching the dried electrodes).

The battery cell assembly process (S200) may include manufacturing the battery cell 10 (see FIG. 3A) by coupling the battery electrodes 14 (see FIG. 3A) to a battery case 12 (see FIG. 3A), and injecting an electrolyte into the battery case 12 (see FIG. 3A), prior to the formation process (S300) and measuring (S350), and may be included in the method for detecting a defect in a battery in a formation process according to an embodiment of the present disclosure.

For example, the battery cell assembly process (S200) may include assembling tab-type battery electrodes 14 (see FIG. 3A) and a separator (e.g., a porous polymer film or a porous nonwoven fabric) in a specific manner (e.g., at least one of winding, stacking, jelly-roll type, Z-folding type, and stack-folding), connecting positive electrodes to each other or negative electrodes to each other by welding the tab-type battery electrodes 14 (see FIG. 3A) to each other, and disposing the welded battery electrodes 14 (see FIG. 3A) in the battery case 12 (see FIG. 3A) and injecting an electrolyte into the battery case 12 (see FIG. 3A). The battery case 12 (see FIG. 3A) may be a pouch-type case including a sealing portion 13 (see FIG. 3A), and may also be implemented as a cylindrical case or a prismatic case depending on design.

The formation process (S300) may include charging at least one battery cell 10 (see FIG. 3A) to allow at least one battery cell 10 (see FIG. 3A) assembled in the battery cell assembly process (S200) to have electrical characteristics. Here, a solid electrolyte interphase layer may be formed on a surface of the negative electrode of the battery electrode 14 (see FIG. 3A), and at least one battery cell 10 (see FIG. 3A) may thus have a microscopic structure capable of continuously performing an electrochemical reaction according to a voltage of the battery electrode 14 (see FIG. 3A).

For example, between the formation process (S300) and the EoL process (S400), a plurality of battery cells 10 (see FIG. 3A) may be stacked and assembled into one battery module. For example, the plurality of battery modules may be assembled into one battery pack or one battery rack.

Subsequent to the formation process (S300), the EoL process (S400) may include inspecting at least one battery cell having electrical characteristics. For example, the inspection may include at least one of inspection of electrical performance (e.g., capacity, charge/discharge voltage/current, internal resistance, or insulation resistance) of at least one battery cell, inspection of performance of a temperature sensor, inspection of performance of a battery management system (BMS), and inspection of an external appearance of the battery cell. A battery for which the EoL process (S400) is completed may be shipped for an eco-friendly vehicle such as an electric vehicle or for an energy storage system.

In general, a voltage pattern of a battery cell resulting from leaving the battery cell for a long period (e.g., several days) during the formation process may be used to detect a defect (e.g., a low-voltage defect) in a battery cell. However, such leaving of the battery cell for a long period (e.g., several days) may act as a limitation in shortening a total period required for the formation process and may cause overall productivity degradation of battery processes.

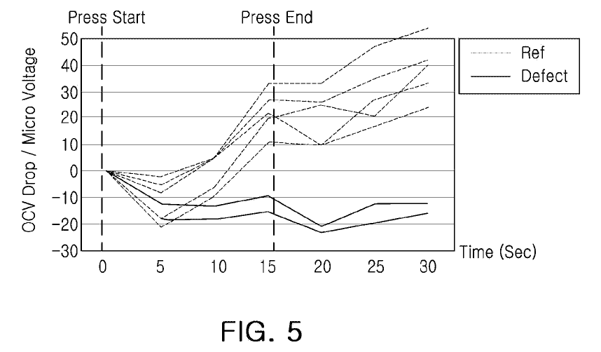

Referring to FIGS. 1 and 5, the method for detecting a defect in a battery in a formation process according to an embodiment of the present disclosure may include detecting a defect in the battery cell (S340) in the formation process (S300), and include the measuring (S350) of pressing the battery cell 10 (see FIG. 3A) in the formation process (S300) and measuring a voltage (open circuit voltage, OCV) of the battery cell 10 (see FIG. 3A) immediately after depressurization by a measuring instrument 151 (see FIG. 3B), and analyzing (S360 and S370) of analyzing (S360) a difference between a pattern of the voltage (OCV) and a reference pattern (Ref) and detecting (S370) a defect (e.g., the low-voltage defect) in the battery cell 10 (see FIG. 3A) based on an analysis result) by a controller 152 (see FIG. 3B).

In the formation process (S300), the battery cell 10 (see FIG. 3A) before stabilization of the voltage (OCV) may have a surface charge imbalance phenomenon. The surface charge imbalance phenomenon may be gradually resolved by leaving the battery cell 10 (see FIG. 3A) for a long period (e.g., several days). However, the depressurization of the battery cell 10 (see FIG. 3A) may resolve the surface charge imbalance phenomenon more rapidly. That is, the depressurization of the battery cell 10 (see FIG. 3A) may promote stabilization of the voltage (OCV) of the battery cell 10 (see FIG. 3A). Therefore, time required for the process (S340) may be shortened (e.g., less than one day), and overall productivity of battery processes including the formation process (S300) may be improved. That is, the analyzing (S360 and S370) may include analyzing the difference between the pattern of the voltage (OCV) and the reference pattern (Ref) within a short time range of less than one day.

A horizontal axial line in FIG. 5 represents time (unit: second), and within a short time range (unit: second) (e.g., from 15 seconds to 30 seconds in FIG. 5), a difference between the reference pattern (Ref) corresponding to a voltage pattern of a battery cell having substantially no defect and a voltage pattern (Defect) of a defective battery cell may be clearly analyzed.

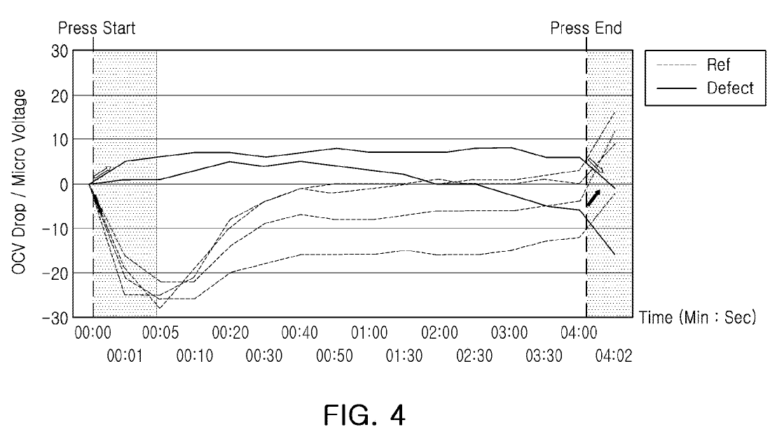

For example, FIG. 5 illustrates five reference patterns (Ref), and in the analyzing (S360 and S370), the controller 152 (see FIG. 3B) may analyze a difference between the reference pattern and a measured voltage pattern (e.g., determining whether a measured voltage deviates from an error range of the reference pattern) by integrating the five reference patterns (Ref) (four reference patterns in FIG. 4) into one pattern including average values at each time point of the five reference patterns (each average value having a predetermined error range), and comparing one integrated reference pattern with the measured pattern.

For example, the reference pattern (Ref) may vary within a voltage range from +10 microvolt (μV) to +55 μV from a press-end time point (Press End) to a time point after a predetermined period (e.g., 15 seconds in FIG. 5), and the voltage pattern (Defect) of the defective battery cell may vary within a voltage range from −10 μV to −25 μV from the press-end time point (Press End) to the time point after the predetermined period (e.g., 15 seconds in FIG. 5).

Internal resistance and equivalent-circuit resistance components of the battery cell 10 (see FIG. 3A) may vary depending on chemical and physical components of in the battery cell 10 (see FIG. 3A). Therefore, a resistance behavior according to the depressurization of the battery cell 10 (see FIG. 3A) may vary depending on resistance characteristics of the battery cell 10 (see FIG. 3A).

For example, foreign substances or pinholes in the battery cell 10 (see FIG. 3A) may be low-voltage defect factors of the battery cell 10 (see FIG. 3A) and may affect a movement distance of an electrolyte of the battery cell 10 (see FIG. 3A) according to the depressurization. For example, when the movement distance of the electrolyte in the battery cell 10 (see FIG. 3A) according to depressurization decreases, the resistance behavior of the battery cell 10 (see FIG. 3A) may minutely change at a milliohm (mΩ) level.

In general, a voltage is analyzed within a large voltage range of millivolt (mV) units or more during the formation process. Therefore, within the large voltage range, it may be difficult to clearly analyze the difference between the reference pattern (Ref) and the voltage pattern (Defect) of the defective battery cell, or to analyze a minute resistance behavior at the mΩ level (or a minute voltage behavior at a μV level).

However, the analyzing (S360 and S370) may include analyzing the difference between the pattern of the voltage (OCV) and the reference pattern (Ref) within the short time range of less than one day and within a minute voltage range of less than 1 mV, and thus analyze the minute resistance behavior at the mΩ level (or the minute voltage behavior at the μV level) according to the depressurization, and clearly analyze the difference between the reference pattern (Ref) and the voltage pattern (Defect) of the defective battery cell within the minute voltage range of less than 1 mV (μV level). That is, the method for detecting a defect in a battery in a formation process according to an embodiment of the present disclosure may not only shorten a total time required for the process (S340) (e.g., less than one day) but also improve battery-cell defect detection performance in the process (S340).

The voltage range may be defined as a difference between the maximum voltage and the minimum voltage within the time range. For example, a voltage range of the reference pattern (Ref) in FIG. 5 may be about 45 μV, and a voltage range of the voltage pattern (Defect) of the defective battery cell in FIG. 5 may be about 15 μV.

Most changes in the chemical and physical components (resistance behavior) according to the depressurization of the battery cell 10 (see FIG. 3A) may occur at an initial stage of the depressurization, the time range and the voltage range may be smaller depending on design. For example, the time range may be less than one hour (e.g., in minute (Min)–second (Sec) units as illustrated in FIG. 4), and the voltage range may be less than 0.1 mV (e.g., a range of about 80 μV from −25 μV to +55 μV in FIG. 5).

Depending on a type of defect in the battery cell 10 (see FIG. 3A), variations (resistance behavior) in the chemical and physical components of the battery cell 10 (see FIG. 3A) according to the depressurization may vary based on whether the battery cell 10 (see FIG. 3A) is defective, and such variations may appear immediately after the depressurization (e.g., for about 15 seconds from Press End in FIG. 5). For example, the time range may start from the press-end time point (Press End) of the battery cell 10 (see FIG. 3A).

For example, a time point at which the difference between the reference pattern (Ref) corresponding to the voltage pattern of the battery cell having substantially no defect and the voltage pattern (Defect) of the defective battery cell is the largest may be about 10 seconds after the press-end time point (Press End). For example, the time range may be 0.1 second or more and less than 20 seconds (e.g., a total of 2 seconds from 4 minutes to 4 minutes and 2 seconds in FIG. 4 and a total of 15 seconds from 15 seconds to 30 seconds in FIG. 5), and the voltage range may be less than 0.05mV (e.g., a range of about 40 μV from −20 μV to +20 μV in FIG. 4).

The analyzing (S360 and S370) may include analyzing a difference between an average of a measured voltage within the time range and an average of a reference voltage. For example, an average voltage difference for 15 seconds from the press-end time point (Press End) between the voltage pattern (Defect) of the defective battery cell and the reference pattern (Ref) in FIG. 5 may be about 0.045 mV (30 μV + 15 μV). Here, the average voltage difference exceeds an error range difference (e.g., 0.02 mV), and the analyzing (S360 and S370) may thus include generating information that a measured battery cell is defective. If the average voltage difference does not exceed the error range difference (e.g., 0.02 mV), the analyzing (S360 and S370) may include generating information that the measured battery cell is normal.

For example, an actual voltage at a press-start time point (Press Start) in FIG. 5 may be higher than 0 V, and the controller 152 (see FIG. 3B) may adjust the actual voltage at the press-start time point (Press Start) to a set voltage (e.g., 0 V). Depending on design, the controller 152 (see FIG. 3B) may adjust the actual voltage to the set voltage (e.g., 0 V) at the press-end time point (Press End) instead of the press-start time point (Press Start).

Voltages in the voltage pattern (Defect) of the defective battery cell and the reference pattern (Ref) at the press-end time point (Press End) of FIG. 5 may differ from each other. This difference may be a result of the difference in voltage change patterns between the voltage pattern (Defect) of the defective battery cell and the reference pattern (Ref) from the press-start time point (Press Start). That is, an average voltage measured immediately after the press-end time point (Press End) may be affected not only by a voltage change pattern measured immediately after the press-end time point (Press End) but also by a voltage change pattern from the press-start time point (Press Start) to the press-end time point (Press End).

Therefore, analyzing a difference between the average of the measured voltage and an average of the reference voltage immediately after the press-end time point (Press End) in the analyzing (S360 and S370) may analyze both a resistance behavior difference according to press and a resistance behavior difference according to the depressurization depending on whether the battery cell is defective, and thus more effectively detect a defect in the battery cell than analyzing the average voltage from the press-start time point (Press Start) to the press-end time point (Press End), and further improve the battery defect detection performance.

The analyzing (S360 and S370) may include analyzing a difference between a slope of the measured voltage from the press-end time point (Press End) of the battery cell 10 (see FIG. 3A) to a time point after a predetermined period (e.g., 2 seconds in FIG. 4 and 15 seconds in FIG. 5) and a slope of the reference voltage. For example, the slope difference for 15 seconds from the press-end time point (Press End) between the voltage pattern (Defect) of the defective battery cell and the reference pattern (Ref) in FIG. 5 may be about 1.5 μV/sec (22.5 μV/15 sec). Here, the slope difference exceeds an error range difference (e.g., 1 μV/sec), and the analyzing (S360 and S370) may thus include generating information that the measured battery cell is defective. If the slope difference does not exceed the error range difference (e.g., 1 μV/sec), the analyzing (S360 and S370) may include generating information that the measured battery cell is normal.

The analyzing (S360 and S370) may include generating the information that the battery cell 10 (see FIG. 3A) is defective when an absolute value of the slope of the measured voltage from the press-end time point (Press End) to a time point after the predetermined period (e.g., 2 seconds in FIG. 4 and 15 seconds in FIG. 5) is greater than an absolute value of the slope of the reference voltage. For example, a difference in absolute values of slopes between the voltage pattern (Defect) of the defective battery cell and the reference pattern (Ref) in FIG. 5 for 5 seconds from the press-end time point (Press End) may be about 2 μV/sec (2 μV/sec − 0 μV/sec). Here, the difference in absolute values of slopes exceeds the error range difference (e.g., 1 μV/sec), and the analyzing (S360 and S370) may thus include generating the information that the measured battery cell is defective. If the difference in absolute values of slopes does not exceed the error range difference (e.g., 1 μV/sec), the analyzing (S360 and S370) may include generating the information that the measured battery cell is normal.

The analyzing (S360 and S370) may include analyzing whether the slope of the measured voltage of the battery cell 10 (see FIG. 3A) from the press-end time point (Press End) to a time point after the predetermined period (e.g., 2 seconds in FIG. 4 and 15 seconds in FIG. 5) is positive or negative, generating the information that the battery cell 10 (see FIG. 3A) is defective when the slope of the measured voltage is one of positive and negative (e.g., negative in FIG. 4), and generating the information that the battery cell 10 is normal when the slope of the measured voltage is the other of positive and negative (e.g., positive in FIG. 4).

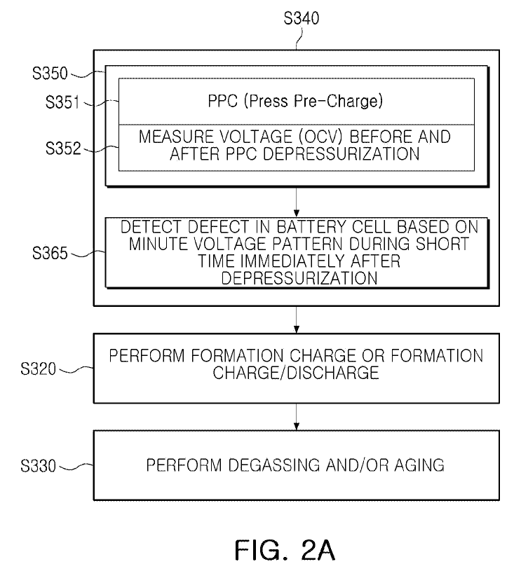

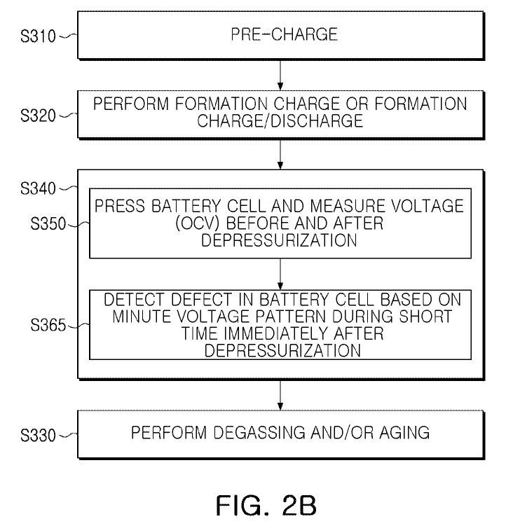

Referring to FIG. 2A, the formation process (S300) in FIG. 1 may include a press pre-charge (PPC) (S351) for performing the pressing and charging of the battery cell 10 (see FIG. 3A) together. Referring to FIG. 2B, the formation process (S300) in FIG. 1 may include a pre-charge (S310) of the battery cell 10 (see FIG. 3A).

Referring to FIGS. 2A and 2B, the formation process (S300) in FIG. 1 may include performing formation charging or formation charge/discharge (charging and discharging) of the battery cell 10 (see FIG. 3A) (S320), and a subsequent process (S330) of performing at least one of aging for stabilizing the battery cell 10 (see FIG. 3A) and degassing for removing gas (e.g., gas occurring during formation of the electrical characteristics) inside the battery cell 10 (see FIG. 3A).

Pressing in the measuring (S350) may include PPC pressing of the battery cell 10 (see FIG. 3A), and may include measuring the voltage (OCV) before and after PPC depressurization (S352). A subsequent analyzing (S365) may include detecting a defect in the battery cell based on a minute voltage pattern (e.g., μV-level) during a short time (e.g., less than one day, less than one hour, or less than 20 seconds) immediately after the depressurization.

For example, the PPC (S351) or the pre-charge process (S310) may include charging the battery cell 10 (see FIG. 3A) by a predetermined capacity (e.g., 20%) for the first time after the battery cell 10 (see FIG. 3A) is assembled. Here, the inside of the battery cell 10 (see FIG. 3A) may be gradually hardened. For example, a charge/discharge device may charge the battery cell 10 (see FIG. 3A) in a constant current mode, and a voltage of the battery cell 10 (see FIG. 3A) may gradually increase according to charging. A press device 120 (see FIG. 3A) may be selectively used depending on a battery type and may press the battery cell 10 (see FIG. 3A) according to a predetermined pressure.

For example, the formation charging or formation charge/discharge (charging and discharging) (S320) may include charging the battery cell 10 (see FIG. 3A) by a capacity greater than the predetermined capacity (e.g., 20%), and may further include discharging the battery cell 10 (see FIG. 3A) to the predetermined capacity (e.g., 20%) depending on design. For example, when the battery cell 10 (see FIG. 3A) is pressed in the PPC (S351) or the pre-charge (S310), S320 may include charging or discharging after the depressurization of the battery cell 10 (see FIG. 3A). Depending on design, one or both of aging and degassing may be included between the PPC (S351) or the pre-charge (S310) and S320. In this case, S320 may be defined as shipment charging.

Referring to FIGS. 3A through 3C, a system 150 for detecting a defect in a battery in a formation process according to an embodiment of the present disclosure may include the press device 120 for pressing the battery cell 10 undergoing the formation process, the measuring instrument 151 for measuring a voltage of the battery cell 10 immediately after the depressurization, and the controller 152 for analyzing the difference between the pattern of the measured voltage (e.g., the voltage pattern (Defect) of the defective battery cell) and the reference pattern (Ref) and detecting a defect (e.g., the low-voltage defect) in the battery cell 10 based on the analysis result. The controller 152 may analyze the difference between the measured voltage pattern and the reference pattern within a short time range of less than one day and within the minute voltage range of less than 1 mV. Accordingly, the system 150 for detecting a defect in a battery in a formation process may not only shorten the time required for the battery defect detection but also improve the battery defect detection performance.

For example, at least one battery cell 10 may be formed by accommodating an electrode assembly including a positive plate, a negative plate, and a separator inside an outer case, injecting an electrolyte into the outer case, and then sealing the outer case. Here, electrodes 14 respectively connected to the positive plate and the negative plate may be exposed an outside of the outer case.

FIG. 3A may correspond to a time point before the press-start time point (Press Start in FIGS. 4 and 5), FIG. 3B may correspond to a period from the press-start time point (Press Start in FIGS. 4 and 5) to the press-end time point (Press End in FIGS. 4 and 5), and FIG. 3C may correspond to a period after the press-end time point (Press End in FIGS. 4 and 5).

For example, the press device 120 may include a plurality of support plates 121 and 122. Referring to FIG. 3A, the battery cell 10 may be disposed between the plurality of support plates 121 and 122. Referring to FIG. 3B, the plurality of support plates 121 and 122 may approach each other to press the battery cell 10 in a vertical direction. Here, the measuring instrument 151 may be electrically connected to electrodes 14 to measure the voltage (OCV) of the battery cell 10. Referring to FIG. 3C, the plurality of support plates 121 and 122 may move away from each other to depressurize the battery cell 10.

For example, each of the plurality of support plates 121 and 122 may be implemented in a polyhedral form having a flat surface (upper and/or lower surface) facing the battery cell 10 and may press the battery cell 10 by receiving a force controlled by the controller 152 in the vertical direction. Depending on design, the plurality of support plates 121 and 122 may be implemented to move only in the vertical direction while their horizontal movement is prevented by fastening members such as bolts or screws. Depending on design, the press device 120 may be implemented as a roller instead of the plurality of support plates 121 and 122, and the roller may press the battery cell 10 by rolling on one surface of the battery cell 10.

For example, a pressure applied by the press device 120 to the battery cell 10 may be 0.1 megapascal (MPa) or more and 10 MPa or less (error range: ±50 kilonewton (kN)) and may be set to be non-destructive not to cause substantial performance degradation or damage to the battery cell 10. A temperature before and after the pressure application of the press device 120 may be room temperature (18°C to 28°C) and may decrease to −10°C or increase to 60°C depending on design, and is not limited thereto.

For example, the measuring instrument 151 may be implemented as a digital multimeter, and may include an analog measurement circuit (e.g., a sampling circuit, a buffer circuit, an amplification circuit, or an analog-to-digital conversion circuit).

For example, the measuring instrument 151 may include a sampling circuit for repeatedly sampling a voltage of the battery cell 10 at short intervals, an envelope detection circuit for detecting a frequency analysis (or Fourier transform-based analysis) of a voltage variation of the battery cell 10, or a timer for counting time and generating time values (which may be included in the controller 152).

For example, the measuring instrument 151 may assign a time value to each sampled voltage, determine whether the voltage of the battery cell increases or decreases based on a difference between adjacent sampled voltages having adjacent time values, and calculate an increase/decrease rate (or slope). Depending on design, the measuring instrument 151 may determine and/or calculate using only sampled voltages having time values included within a predetermined time range among the time values of the sampled voltages.

For example, the controller 152 may be implemented as a data acquisition system and may include a computing system (e.g., a microcontroller, a programmable logic controller (PLC), an embedded system, or a manufacturing execution system (MES)). For example, the computing system may include a processor (e.g., a central processing unit (CPU) or a graphics processing unit (GPU)), a memory (e.g., a volatile memory or a non-volatile memory), a recording medium, an input/output device, and a communication device. For example, the controller 152 may operate by executing at least one program (and/or algorithm or logic) recorded in the memory or a storage by the processor, and such operation may correspond to an instruction in the program and correspond to an operation executed by the method for detecting a defect in a battery in a formation process according to an embodiment of the present disclosure. For example, the controller 152 may store the reference pattern (Ref) in FIG. 4 in the memory and analyze the pattern by using the processor.

A horizontal axial line in FIG. 4 represents time (unit: minute and second), and within a short time range (unit: minute and second), the difference between the reference pattern (Ref) corresponding to the voltage pattern of the battery cell having substantially no defect and the voltage pattern (Defect) of the defective battery cell may be clearly analyzed. For example, the actual voltage at 0 seconds may be higher than 0 V, and the controller 152 may adjust the actual voltage to the set voltage (e.g., 0 V) at 0 seconds in FIG. 4.

Depending on design, the measuring (S350) in FIG. 1 may further include measuring a voltage of the battery cell 10 (see FIG. 3A) before the press-end time point (e.g., 4 minutes in FIG. 4) (e.g., at a time point between 0 minutes and 4 minutes in FIG. 4), and the analyzing (S360 and S370) in FIG. 1 may further include analyzing a difference between a voltage change pattern from a voltage measured before the depressurization to a voltage measured immediately after the depressurization of the battery cell 10 (see FIG. 3A) and a reference voltage change pattern. Accordingly, an unintended minute mismatch between the press-end time point and a set measurement start time point may be prevented from reducing analysis accuracy.

For example, from the press-end time point (e.g., 4 minutes) to a time point after a predetermined period (e.g., 2 seconds), the reference pattern (Ref) may increase by about 12 μV, and the voltage pattern (Defect) of the defective battery cell may decrease by about 8 μV.

The reference pattern (Ref) and the voltage pattern (Defect) of the defective battery cell may differ from each other as shown in FIG. 4 and FIG. 5. This difference may be a result of a difference in models (types or kinds) of the battery cells of FIGS. 4 and 5, and the resistance behavior (internal resistance and equivalent-circuit resistance components) according to the depressurization may also differ from each other as shown in FIG. 4 and FIG. 5.

For example, the reference pattern (Ref) in FIG. 4 may increase for at least 2 seconds from the press-end time point (e.g., 4 minutes), and the reference pattern (Ref) in FIG. 5 may increase for at least 10 seconds from 5 seconds after the press-end time point (e.g., 4 minutes). Therefore, an analysis time range for a battery cell model corresponding to the reference pattern (Ref) in FIG. 4 may precede and be shorter than an analysis time range for the reference pattern (Ref) in FIG. 5.

For example, a difference between a voltage at the press-start time point (Press Start) and a voltage at the press-end time point (Press End) in FIG. 4 may be small in both the reference pattern (Ref) and the voltage pattern (Defect) of the defective battery cell. In contrast, a difference between a voltage at the press-start time point (Press Start) and a voltage at the press-end time point (Press End) in FIG. 5 may be greater in the reference pattern (Ref) than in the voltage pattern (Defect) of the defective battery cell. Therefore, a slope analysis of the pattern may be more advantageous for a battery cell model corresponding to the reference pattern (Ref) in FIG. 4, and an average voltage analysis of the pattern may be more advantageous for a battery cell model corresponding to the reference pattern (Ref) in FIG. 5.

For example, different models (types or kinds) may refer to different shapes (e.g., pouch type, prismatic type, cylindrical type) or may refer to different materials (e.g., lithium iron phosphate (LFP), lithium nickel manganese cobalt oxide (LiNiMnCoO₂, NCM), medium-nickel (mid-Ni), or high-nickel (high-Ni).

As set forth above, the method and the system for detecting a defect in a battery in a formation process according to an embodiment of the present disclosure may efficiently detect a defect (e.g., the low-voltage defect) in the battery during the formation process (e.g., not only shortening the time required for detecting a battery defect but also improving the battery defect detection performance).

For example, the process of leaving the battery cell for a long period (e.g., several days) during the formation process to detect a defect (e.g., the low-voltage defect) in the battery cell may be omitted.

Only specific examples of implementations of certain embodiments are described. Variations, improvements and enhancements of the disclosed embodiments and other embodiments may be made based on the disclosure of this patent document.

What is claimed is:

1. A method for detecting a defect in a battery in a formation process, the method comprising:
measuring a voltage of a battery cell immediately after depressurization of a pressurized battery cell in the formation process; and
analyzing a difference between a pattern of the voltage and a reference pattern and detecting a defect in the battery cell based on an analysis result,
wherein the analyzing includes analyzing the difference between the voltage pattern and the reference pattern within a short time range of less than one day and within a minute voltage range of less than 1 millivolt (mV).

2. The method of claim 1, wherein the time range is less than one hour, and the voltage range is less than 0.1 mV.

3. The method of claim 1, wherein the time range is less than 20 seconds, and the voltage range is less than 0.05 mV.

4. The method of claim 1, wherein the time range starts from a press-end time point of the battery cell.

5. The method of claim 1, wherein the depressurization includes depressurization of press pre-charge (PPC) of the battery cell.

6. The method of claim 1, further comprising:
a subsequent process of performing at least one of aging for stabilizing the battery cell or degassing for removing gas inside the battery cell, after the analyzing.

7. The method of claim 1, further comprising:
manufacturing the battery cell by coupling a battery case to battery electrodes and injecting an electrolyte into the battery case, prior to the measuring.

8. The method of claim 1, wherein the measuring further includes measuring a voltage of the battery cell before the depressurization, and
the analyzing further includes analyzing the difference between the voltage change pattern from the voltage of the battery cell measured before the depressurization to the voltage measured after the depressurization and a reference voltage change pattern.

9. The method of claim 1, wherein the analyzing includes analyzing a difference between an average of the voltage within the time range and an average of a reference voltage.

10. The method of claim 1, wherein the analyzing includes analyzing a difference between a slope of the voltage from a press-end time point of the battery cell to a time point after a predetermined period and a slope of a reference voltage.

11. The method of claim 10, wherein the analyzing includes generating information that the battery cell is defective when an absolute value of the slope of the voltage from the press-end time point to the time point after the predetermined period is greater than an absolute value of the slope of the reference voltage.

12. The method of claim 10, wherein the analyzing includes
analyzing whether the slope of the voltage from the press-end time point to the time point after the predetermined period is positive or negative,
generating information that the battery cell is defective when the slope of the voltage is one of positive and negative, and
generating information that the battery cell is normal when the slope of the voltage is the other of positive and negative.

13. A system for detecting a defect in a battery in a formation process, the system comprising:
a press device for pressing a battery cell undergoing the formation process;
a measuring instrument for measuring a voltage of the battery cell immediately after depressurization; and
a controller for analyzing a difference between a pattern of the voltage and a reference pattern and detecting a defect in the battery cell based on an analysis result,
wherein the controller analyzes the difference between the voltage pattern and the reference pattern within a short time range of less than one day and within a minute voltage range of less than 1 millivolt (mV).

14. The system of claim 13, wherein the time range is less than one hour, the voltage range is less than 0.1 mV, and the time range starts from a press-end time point of the battery cell.

15. The system of claim 14, wherein the time range is less than 20 seconds, and the voltage range is less than 0.05 mV.

16. The system of claim 13, wherein the pressing includes press pre-charge (PPC) pressing of the battery cell.

17. The system of claim 13, wherein the measuring instrument further measures a voltage of the battery cell before the depressurization, and
the controller further analyzes the difference between the voltage change pattern from the voltage of the battery cell measured before the depressurization to the voltage measured after the depressurization and a reference voltage change pattern.

18. The system of claim 13, wherein the controller analyzes a difference between an average of the voltage within the time range and an average of a reference voltage, or
analyzes a difference between a slope of the voltage from a press-end time point of the battery cell to a time point after a predetermined period and a slope of the reference voltage.

19. The system of claim 18, wherein the controller includes generating information that the battery cell is defective when an absolute value of a slope of the voltage from the press-end time point to the time point after the predetermined period is greater than an absolute value of the slope of the reference voltage.

20. The system of claim 18, wherein the controller analyzes whether the slope of the voltage from the press-end time point to the time point after the predetermined period is positive or negative,
generates information that the battery cell is defective when the slope of the voltage is one of positive and negative, and
generates information that the battery cell is normal when the slope of the voltage is the other of positive and negative.
